(19) United States
(12) Patent Application Publication
(10) Pub. No.: US 2022/0080650 A1
(43) Pub. Date: Mar. 17, 2022

(54) IMPRINT DEVICE, INFORMATION PROCESSING DEVICE, AND IMPRINT METHOD

(71) Applicant: Kioxia Corporation, Tokyo (JP)

(72) Inventor: Hirotaka TSUDA, Yokkaichi Mie (JP)

(73) Assignee: Kioxia Corporation, Tokyo (JP)

(21) Appl. No.: 17/198,440

(22) Filed: Mar. 11, 2021

(30) Foreign Application Priority Data
Sep. 16, 2020 (JP) 2020-155868

(51) Int. Cl. B29C 59/00; B29C 59/18

(52) U.S. Cl. CPC B29C 59/007; B29C 59/18

(57) ABSTRACT

An imprint device of an embodiment includes an imaging device and a controller. The controller acquires, from the imaging device, a reference image which is a captured image of the template before the imprint operation at a predetermined imprint position and an imprint image which is a captured image of the template during the imprint operation at the imprint position. The control unit acquires features based on interference fringes appearing on the template during the imprint operation from a difference image representing a difference between the reference image and the imprint image. The control unit performs processes for controlling the imprint operation based on the features.

### CROSS-REFERENCE TO RELATED APPLICATIONS

This application is based upon and claims the benefit of priority from Japanese Patent Application No. 2020-155868, filed on Sep. 16, 2020; the entire contents of which are incorporated herein by reference.

### FIELD

Embodiments described herein relate generally to an imprint device, an information processing device, and an imprint method.

### BACKGROUND

In a manufacturing process of a semiconductor device, an imprint process is used as a method for forming a fine pattern. The imprint process includes an imprint operation in which a template as an original plate on which a pattern is formed is pressed against a resin film disposed on a substrate. As a method for evaluating whether the imprint operation is properly performed, there is a method of detecting, from a captured image, interference fringes (Newton rings) appearing on the template during the imprint operation.

An object of an embodiment of the present invention is to provide an imprint device, an information processing device, and an imprint method capable of evaluating an imprint operation based on interference fringes with high accuracy.

### BRIEF DESCRIPTION OF THE DRAWINGS

FIG. 1 is a schematic view illustrating an example of a template configuration according to an embodiment;

FIG. 2 is a schematic view illustrating an example of a wafer configuration according to the embodiment;

FIG. 3 is a view illustrating a configuration example of an imprint device according to the embodiment;

FIG. 4 is a view illustrating an example of a procedure in a semiconductor device manufacturing method according to the embodiment;

FIG. 5 is a view schematically illustrating an example of a state at the time of imprint operation of the template according to the embodiment;

FIG. 6 is a view illustrating an example of changes in interference fringes with the progress of the imprint operation;

FIG. 7 is a view schematically illustrating an example in a case where the imprint operation is performed in a biased state;

FIG. 8 is a view illustrating an example of the interference fringes appearing in the state illustrated in FIG. 7;

FIG. 9 is a view illustrating an example of an image of the interference fringes at the time of a partial shot region;

FIG. 10 is a view illustrating an example of changes in the interference fringes with the progress of the imprint operation at the time of a partial shot region;

FIG. 11 is a diagram illustrating an example of a hardware configuration of a control unit according to the embodiment;

FIG. 12 is a diagram illustrating an example of a functional configuration of the control unit according to the embodiment;

FIG. 13 is a diagram illustrating an example of the interference fringes analysis method using difference images according to the embodiment;

FIG. 14 is a diagram illustrating parameters related to features according to a first example;

FIG. 15 is a graph illustrating an example of changes over time in the features according to the first example;

FIG. 16 is a graph illustrating an example of changes over time in features according to a second example;

FIG. 17 is a graph illustrating an example of changes over time in features according to a third example;

FIG. 18 is a diagram illustrating parameters related to features according to a fourth example;

FIG. 19 is a graph illustrating an example of changes over time in the features according to the fourth example;

FIG. 20 is a diagram illustrating parameters related to features according to a fifth example;

FIG. 21 is a graph illustrating an example of changes over time in the features according to the fifth example; and

FIG. 22 is a graph illustrating an example of changes over time in features according to a sixth example.

### DETAILED DESCRIPTION

An imprint device according to an embodiment forms a predetermined pattern on a resin film disposed on a substrate by using an imprint operation of pressing a template against the resin film. The imprint device includes: a holder that holds a template, a stage on which a substrate is mounted, an imaging device that acquires a captured image of the template, and a controller that performs processes for controlling the imprint operation of pressing the template against the resin film arranged on the substrate based on the captured image. The controller acquires, from the imaging device, a reference image which is a captured image of the template before the imprint operation at a predetermined imprint position and an imprint image which is a captured image of the template during the imprint operation at the imprint position, acquires features based on interference fringes appearing on the template during the imprint operation from a difference image representing a difference between the reference image and the imprint image, and performs processes for controlling the imprint operation based on the features.

Hereinafter, embodiments of the present invention will be described with reference to the drawings. The present invention is not limited to the following embodiments. In addition, constituent elements in the following embodiments include those that can be easily assumed by those skilled in the art or those that are substantially the same.

(Example of Template and Wafer Configurations)

The imprint process presses a template on which fine patterns are formed against a resist on a wafer (substrate) to transfer the fine patterns of the template to the resist. The resist is an example of a “resin film” that is applied on a wafer to form a pattern on the wafer.

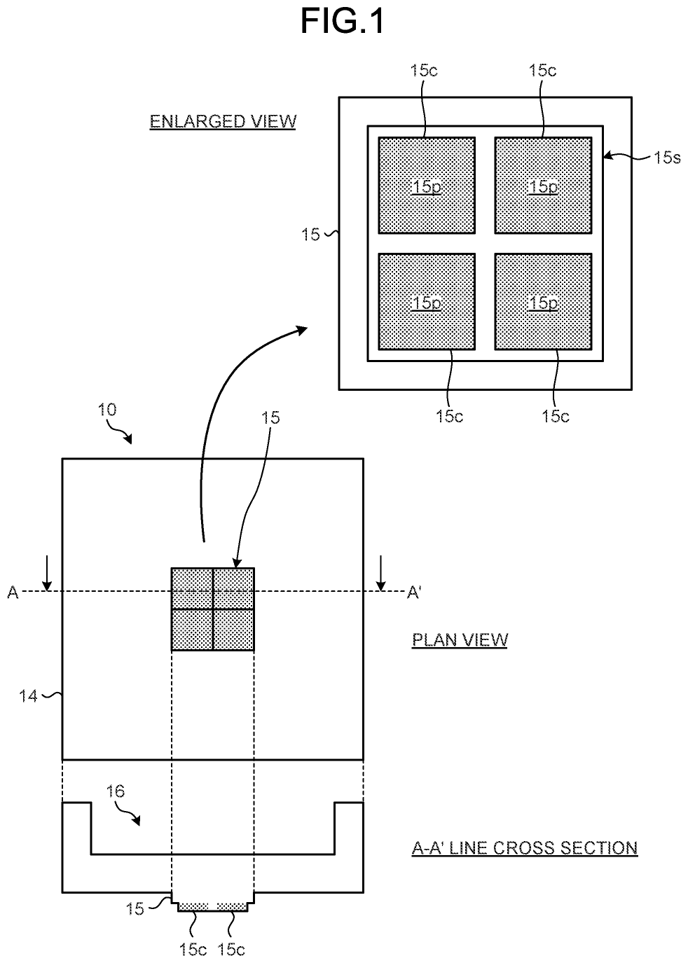

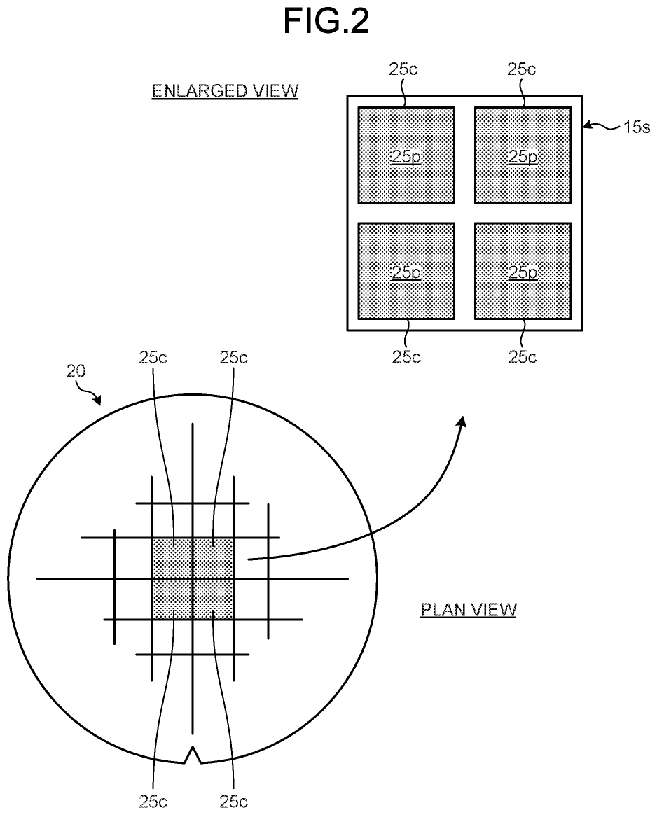

Hereinafter, a configuration example of a template 10 and a wafer 20 of the embodiment will be described with reference to FIGS. 1 and 2.

FIG. 1 is a schematic view illustrating an example of a configuration of the template 10 according to the embodiment. The template 10 of the embodiment is formed of a transparent member such as crystal or glass.

As illustrated in FIG. 1, the template 10 as an original plate includes, for example, a rectangular template substrate 14. There is provided a mesa portion 15 on the front surface of the template substrate 14, and a counterbore 16 is provided on the back surface.

The mesa portion 15 is arranged in the central portion of the template substrate 14, and has a rectangular shape, for example. The mesa portion 15 includes a shot region 15s. The shot region 15s is a region that is patterned on the resist on the wafer by one imprint operation. The shot region 15s includes, for example, a plurality of pattern regions 15c in which nano-scale fine patterns 15p are formed. Examples of the fine pattern 15p can include a pattern having a plurality of grooves, a pattern having a plurality of dots, or the like. Furthermore, the shot region 15s may include a mark or the like for alignment.

The configuration of the template 10 illustrated in FIG. 1 is merely an example, and is not limited to this. For example, in the example of FIG. 1, four pattern regions 15c are arranged in one shot region 15s. However, the number and arrangement of the pattern regions 15c are not limited to this example.

FIG. 2 is a schematic view illustrating an example of a configuration of the wafer 20 according to the embodiment. As illustrated in FIG. 2, the wafer 20 includes a plurality of chip regions 25c on the entire surface of the wafer 20, for example. The chip region 25c is a region diced into a chip at the end of the manufacturing process of a semiconductor device. The chip region 25c includes an element portion 25p. A mark or the like for alignment may be provided on the outside of the element portion 25p.

In the state where the wafer 20 and the template 10 are aligned, four chip regions 25c are arranged so as to fit within one shot region 15s of the template 10, for example. That is, one chip region 25c is a region substantially equal to one pattern region 15c. In the element portion 25p, the pattern is transferred to the resist by the imprint process. That is, the element portion 25p is arranged at a position corresponding to the fine pattern 15p of the template 10.

The configuration of the wafer 20 illustrated in FIG. 2 is merely an example, and can be changed together with the configuration of the template 10.

(Configuration Example of Imprint Device)

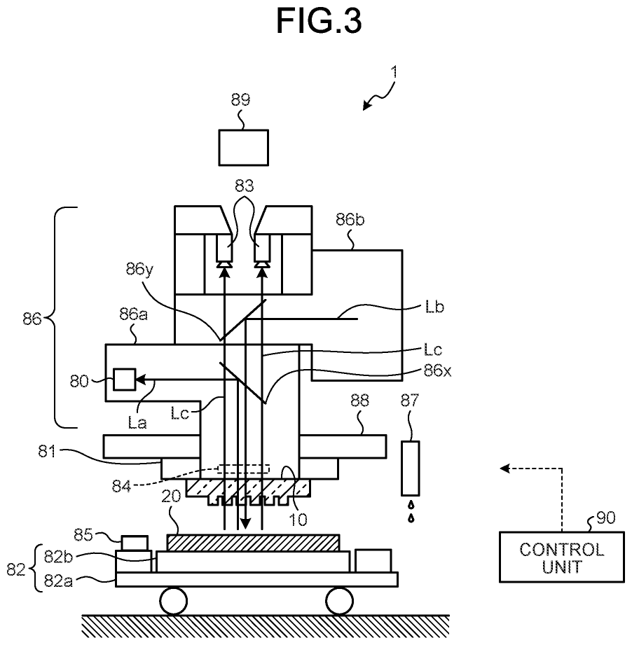

FIG. 3 is a view illustrating a configuration example of an imprint device 1 according to the embodiment. As illustrated in FIG. 3, the imprint device 1 includes a template stage 81 (holder), a wafer stage 82 (stage), an alignment scope 83, a reference mark 85, an alignment unit 86, an imaging unit 80 (imaging device), a droplet dispenser device 87, a stage base 88, a light source 89, and a control unit 90. The template 10 for transferring a fine pattern to the resist on the wafer 20 is installed on the imprint device 1.

The wafer stage 82 includes a wafer chuck 82b and a main body 82a. The wafer chuck 82b fixes the wafer 20 at a predetermined position on the main body 82a. The reference mark 85 is provided on the wafer stage 82. The reference mark 85 is used for alignment at loading of the wafer 20 onto the wafer stage 82.

The wafer stage 82 is a stage on which the wafer 20 is mounted and moves in a plane parallel to the mounted wafer 20 (within a horizontal plane). The wafer stage 82 moves the wafer 20 to the lower side of the droplet dispenser device 87 when dispensing the resist on the wafer 20, and moves the wafer 20 to the lower side of the template 10 when performing the transfer process on the wafer 20.

The stage base 88 supports the template 10 by the template stage 81 and moves in the up-down direction (vertical direction) so as to bring the fine pattern of the template 10 to be pressed against the resist on the wafer 20. Furthermore, the template stage 81 has a pressurizing unit 84 that applies back pressure to the counterbore 16 of the template 10. The action and effect, and the like of back pressure will be described below.

The alignment unit 86 is provided on the stage base 88. The alignment unit 86 detects the position of the wafer 20 and the position of the template 10 based on alignment marks or the like provided on the wafer 20 and the template 10.

The alignment unit 86 includes a detection system 86a and an illumination system 86b. The illumination system 86b irradiates the wafer 20 and the template 10 with light. The detection system 86a detects an image such as an alignment mark provided on the wafer 20 and the template 10 by the alignment scope 83 or other imaging elements, and aligns the wafer 20 and the template 10 based on the detection result. Furthermore, the detection system 86a includes the imaging unit 80 that acquires a captured image of the template 10 before and during the execution of the imprint operation.

The detection system 86a and the illumination system 86b include mirrors 86x and 86y such as a dichroic mirror as a focusing unit, respectively. The mirrors 86x and 86y focus an image originated from the wafer 20 and the template 10 by the light from the illumination system 86b. Specifically, light Lb from the illumination system 86b is reflected by the mirror 86y downward where the template 10 and the wafer 20 are arranged. Furthermore, light La from the template 10 is reflected by the mirror 86x toward the detection system 86a and travels to the imaging unit 80. Furthermore, part of light Lc from the template 10 is transmitted through the mirrors 86x and 86y and travels to the upper alignment scope 83.

The light La from the template 10 is acquired by the imaging unit 80 as a captured image obtained by capturing an upper surface of the template 10. The imaging unit 80 acquires a captured image (reference image) of the template 10 before execution of the imprint operation of pressing the template 10 against the resist on the wafer 20 at a predetermined imprint position, and acquires a captured image (imprint image) of the template 10 during the imprint operation at the imprint position. The reference image and the imprint image will be described below. The present embodiment is an exemplary configuration in which the imaging unit 80 that acquires the reference image and the imprint image is provided in the detection system 86a. However, the configuration of the imaging unit 80 is not limited to this example. The specific configuration of the imaging unit 80 should be appropriately selected in accordance with the usage situation or the like.

The droplet dispenser device 87 is a device that dispenses a resist onto the wafer 20 by an inkjet method. An inkjet head included in the droplet dispenser device 87 has a plurality of micropores for ejecting resist droplets, through which the resist droplets are dispensed onto the wafer 20.

Although the imprint device 1 of the embodiment is configured to dispense the resist as droplets, the resist may be applied to the entire surface of the wafer 20 by the spin coating method.

The light source 89 as a transfer unit is a device that emits ultraviolet rays, for example, and is provided above the stage base 88. The light source 89 emits light from above the template 10 with the template 10 pressed against the resist.

The control unit 90 (controller) is an information processing device that performs various processes for controlling the imprint device 1. The control unit 90 includes a computer that performs predetermined arithmetic processing and control processing according to a program. The control unit 90 according to the present embodiment controls a mechanism related to the imprint operation (including the stage base 88, the template stage 81, the pressurizing unit 84, the wafer stage 82, the droplet dispenser device 87, and the like) based on the captured image acquired by the imaging unit 80.

(Method for Manufacturing Semiconductor Device)

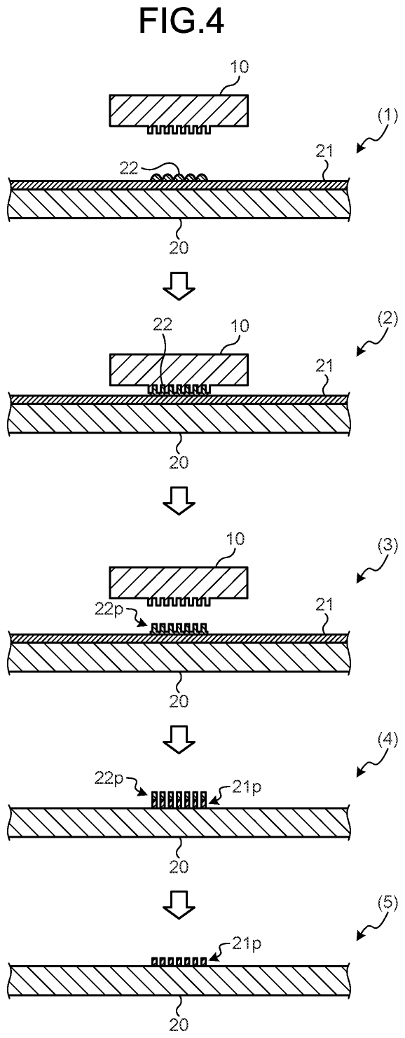

Next, with reference to FIG. 4, an example of a method for manufacturing a semiconductor device including an imprint process using the imprint device 1 according to the embodiment will be described. FIG. 4 is a view illustrating an example of a procedure in a semiconductor device manufacturing method according to the embodiment.

As illustrated in State (1), a film to be processed 21 is formed on the wafer 20 as a semiconductor substrate, and the resist 22 is dispensed as droplets onto the film to be processed 21.

Specifically, the wafer 20 on which the film to be processed 21 is formed is mounted on the wafer stage 82. Subsequently, the wafer stage 82 is moved below the droplet dispenser device 87, and the droplets of the resist 22 are dispensed onto the film to be processed 21 from the droplet dispenser device 87.

As described above, the resist 22 may be applied on the entire surface of the wafer 20 by the spin coating method.

Thereafter, the wafer stage 82 is moved below the template 10.

Next, as illustrated in State (2), the template stage 81 is moved downward, and the fine pattern of the template 10 is pressed against the resist 22 under alignment performed by the alignment unit 86.

Subsequently, with the template 10 pressed, the resist 22 is irradiated with light from the light source 89 of the imprint device 1 to cure the resist 22. With this procedure, the fine pattern of the template 10 is transferred to the resist 22.

Next, the template 10 is released as illustrated in State (3). With this operation, a resist pattern 22p to which the fine pattern is transferred is formed on the film to be processed 21 of the wafer 20.

Next, as illustrated in State (4), the film to be processed 21 is processed using the resist pattern 22p to which the fine pattern is transferred as a mask. This leads to formation of a pattern on the film to be processed 21p.

Next, as illustrated in State (5), the resist pattern 22p is removed by asking or the like to obtain the pattern on the film to be processed 21p formed on the wafer 20.

Thereafter, by repeating the above processes to form a plurality of the patterns on the film to be processed on the wafer 20, the semiconductor device will be manufactured.

(Interference Fringes)

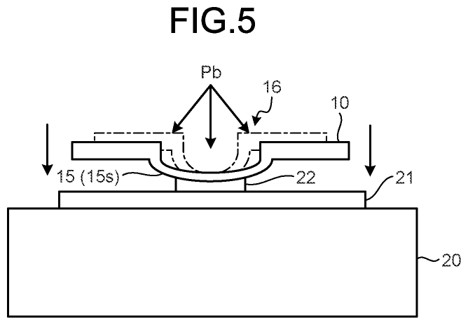

Next, interference fringes (Newton rings) appearing on the template 10 during the imprint operation will be described with reference to FIGS. 5 to 10.

FIG. 5 is a view schematically illustrating an example of a state at the time of imprint operation of the template 10 according to the embodiment. As illustrated in FIG. 5, during the imprint operation, that is, when the mesa portion 15 (shot region 15s) of the template 10 is going to be pressed against the resist 22, back pressure Pb is applied to the counterbore 16 of the template 10 so as to deform the mesa portion 15 into a convex lens shape that protrudes downward (resist 22 side). This makes it possible to apply the pressure onto the resist 22 in gradually expanding manner outward from the central portion of the shot region 15s, leading to uniform spreading of the resist 22.

When performing the imprint operation as described above, interference fringes due to distortion of the mesa portion 15 appear on the upper surface of the template 10 (surface opposite to the surface facing the resist 22).

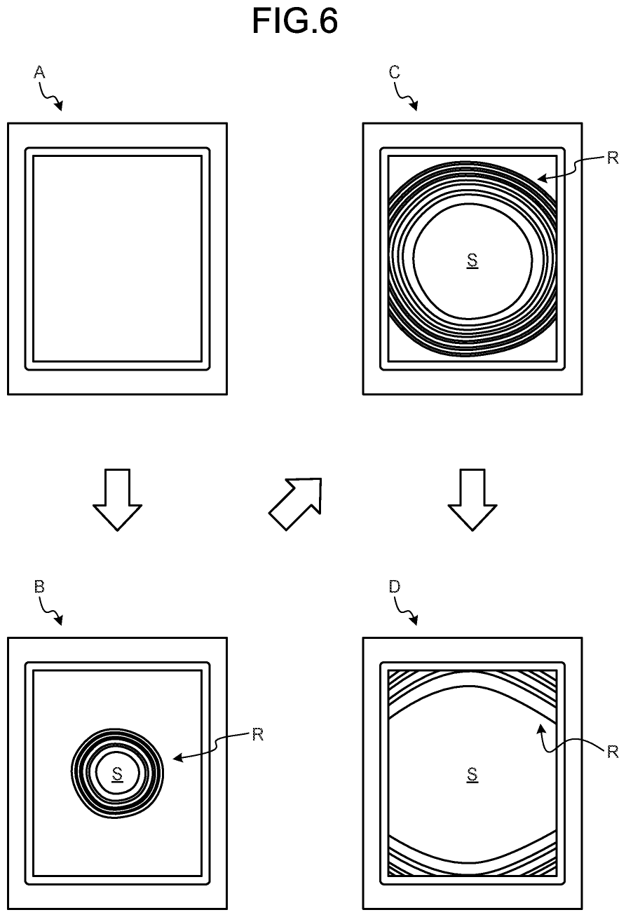

FIG. 6 is a view illustrating an example of changes in interference fringes R together with the progress of the imprint operation. FIG. 6 illustrates a plurality of imprint images A to D acquired by the imaging unit 80 with the progress of the imprint operation. The imprint image A is a captured image of the upper surface of the template 10 at the start (immediately after the start) of the imprint operation, in which interference fringes have not yet appeared at this point. The imprint image B is a captured image of the upper surface of the template 10 at the timing when the template 10 advances toward the wafer 20 side with respect to the time when the imprint image A is captured. The imprint image B includes an image of the interference fringes R appearing around a contact region S between the template 10 and the resist 22. The imprint image C is a captured image of the upper surface of the template 10 at the timing when the template 10 further advances toward the wafer 20 side compared to the time when the imprint image B is captured. The interference fringes R in the imprint image C are wider than the interference fringes R in the imprint image B. The imprint image D is a captured image of the upper surface of the template 10 at the timing when the template 10 further advances toward the wafer 20 side compared to the time when the imprint image C is captured. The interference fringes R in the imprint image D are further wider than the interference fringes R in the imprint image C. In this manner, the interference fringes R (contact region S) expand with the progress of the imprint operation.

The example illustrated in FIG. 6 is an example when the imprint operation is normally performed. In this case, the interference fringes R spread concentrically as illustrated in FIG. 6. However, when the imprint operation is performed in a biased state (for example, when the template 10 is tilted with respect to the wafer 20, the pressure of the template 10 on the resist 22 varies, the back pressure Pb varies, etc.), the interference fringes R will develop in a biased manner.

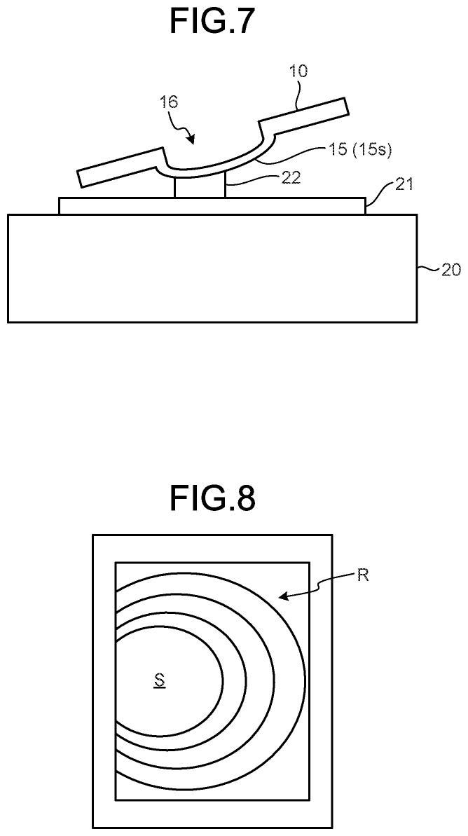

FIG. 7 is a view schematically illustrating an example in a case where the imprint operation is performed in a biased state. FIG. 8 is a view illustrating an example of the interference fringes R appearing in the state illustrated in FIG. 7. FIG. 7 illustrates a state in which the template 10 is tilted with respect to the wafer 20. In such a case, as illustrated in FIG. 8, the development of the interference fringes R is not concentric but biased. By detecting the biasing of the interference fringes R, it is possible to perform evaluation, correction, or the like, regarding the imprint operation.

The example illustrated in FIG. 6 is an example at the time of a full shot region in which the imprint position is relatively far from the edge of the wafer 20 and the image of the edge of the wafer 20 is not included in the imprint images A to D. In such a case, the interference fringes R can be detected with relatively high accuracy. However, at the time of a partial shot region in which the imprint position is close to the edge of the wafer 20, the image of the edge of the wafer 20 is included in the imprint images A to D. Therefore, the image of the edge of the wafer 20 would be a noise component, leading to a problem of deterioration of the detection accuracy of the interference fringes R.

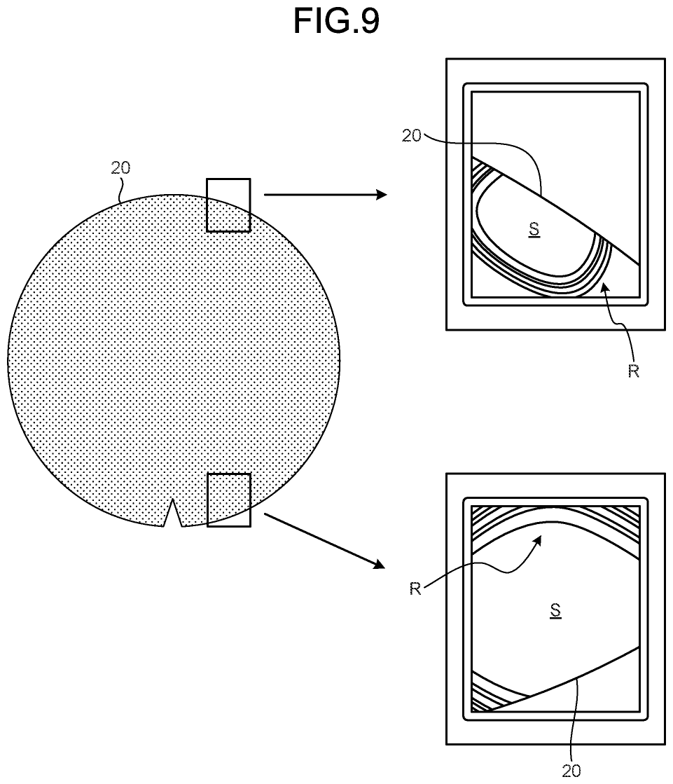

FIG. 9 is a view illustrating an example of an image of the interference fringes R at the time of a partial shot region. FIG. 9 illustrates a state in which the flow edge (edge of the contact region S) of the resist 22 reaches the edge of the wafer 20 and the interference fringes R are cut at the edge of the wafer 20. In such a case, the image at the edge of the wafer 20 would be a noise component, leading to the deterioration of the detection accuracy of the interference fringes R in some cases.

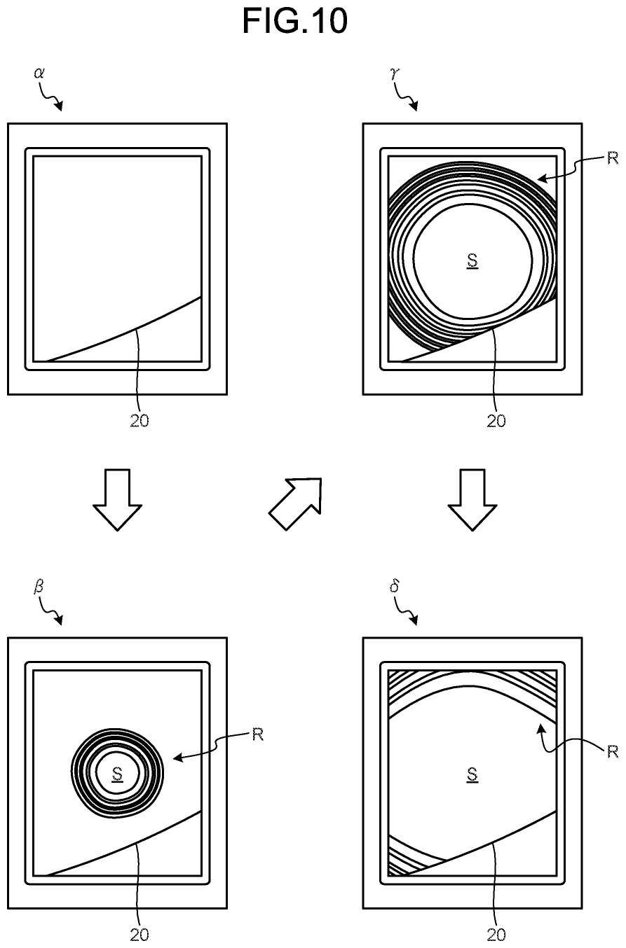

FIG. 10 is a view illustrating an example of changes in the interference fringes R with the progress of the imprint operation at the time of a partial shot region. FIG. 10 illustrates a plurality of imprint images α to 6 acquired with the progress of the imprint operation.

The imprint image α is a captured image of the upper surface of the template 10 at the start (immediately after the start) of the imprint operation. The imprint image α includes an image of the edge of the wafer 20. The imprint image β is a captured image of the upper surface of the template 10 at the timing when the template 10 advances toward the wafer 20 side compared to the time when the imprint image α is captured. The imprint image β includes an image of the interference fringes R appearing around the contact region S and an image of the edge of the wafer 20. At this timing, the interference fringe R has not yet reached the edge of the wafer 20. The imprint image γ is a captured image of the upper surface of the template 10 at the timing when the template 10 further advances toward the wafer 20 side compared to the time when the imprint image β is captured. The interference fringes R in the imprint image γ are wider than the interference fringes R in the imprint image β, and a part thereof reaches the edge of the wafer 20. The imprint image δ is a captured image of the upper surface of the template 10 at the timing when the template 10 further advances toward the wafer 20 side compared to the time when the imprint image γ is captured. The interference fringes R in the imprint image δ are further widened than the interference fringes R in the imprint image γ, and the contact region S (flow edge of the resist 22) and the interference fringes R reach the edge of the wafer 20.

When the interference fringe R or the contact region S reaches the edge of the wafer 20 as illustrated in the imprint images γ and δ, the edge of the wafer 20 would be a noise component, leading to deterioration of the detection accuracy of the interference fringes R. The control unit 90 according to the present embodiment includes a means for solving the above problems.

(Example of Hardware Configuration of Control Unit)

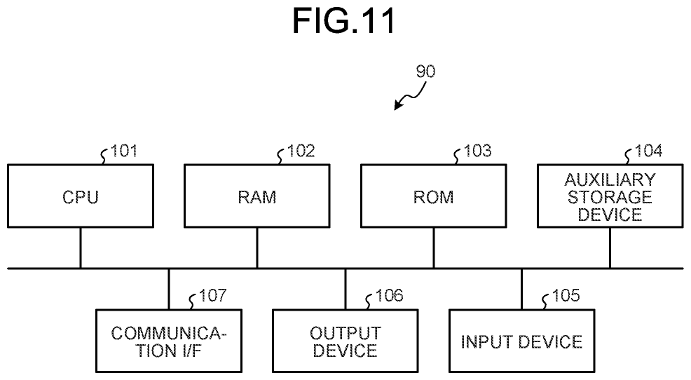

FIG. 11 is a diagram illustrating an example of a hardware configuration of the control unit 90 according to the embodiment. The control unit 90 includes a central processing unit (CPU) 101, a random access memory (RAM) 102, a read only memory (ROM) 103, an auxiliary storage device 104, an input device 105, an output device 106, and a communication interface (I/F) 107.

The CPU 101 is an integrated circuit that performs arithmetic processing following a program, and performs processing for controlling the entire operation of the imprint device 1. The RAM 102 is a volatile storage device capable of high-speed data reading and writing and functions as a work area of the CPU 101. The ROM 103 is a read-only non-volatile storage device that stores programs such as firmware. The auxiliary storage device 104 is a non-volatile storage device capable of data reading and writing, and stores programs such as an operating system (OS) and applications. The input device 105 is a device that receives a user's input operation, examples of which including a keyboard, a mouse, and a touch panel. The output device 106 is a device that outputs internally generated information to the user, examples of which including a display and a speaker. The communication I/F 107 is a device that enables transmission and reception of signals to and from an external device (an imaging element 83, etc.) via a computer network.

The above configuration is an example, and the hardware configuration of the control unit 90 should be appropriately designed depending on the usage situation. For example, in addition to the above configuration, the control unit 90 may include an application specific integrated circuit (ASIC) or the like specialized for image processing.

(Example of Functional Configuration of Control Unit)

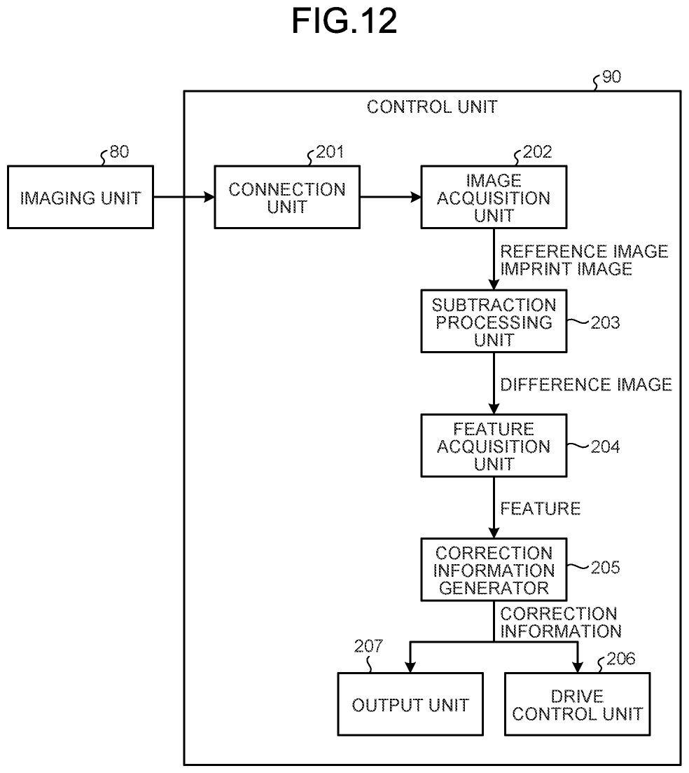

FIG. 12 is a diagram illustrating an example of a functional configuration of the control unit 90 according to the embodiment. The control unit 90 includes a connection unit 201, an image acquisition unit 202, a subtraction processing unit 203, a feature acquisition unit 204, a correction information generator 205, a drive control unit 206, and an output unit 207. These functional units 201 to 207 are implemented by the cooperation of the hardware component of the control unit 90 as illustrated in FIG. 11 and the program (software component) that controls the CPU 101.

The connection unit 201 is communicatively connected to the imaging unit 80 and inputs image data output from the imaging unit 80.

The image acquisition unit 202 acquires the captured image of the template 10 from the image data input via the connection unit 201. The captured images acquired by the image acquisition unit 202 include both a reference image which is a captured image of the template 10 before the imprint operation at a predetermined imprint position and an imprint image which is a captured image of the template 10 during the imprint operation at the imprint position.

The subtraction processing unit 203 performs a subtraction process of subtracting the reference image from the imprint image and thereby generates a difference image illustrating a difference between the imprint image and the reference image.

The feature acquisition unit 204 acquires, from the difference image, features based on the interference fringes R appearing on the template 10 (upper surface of the template 10) during the imprint operation.

The correction information generator 205 generates correction information for correcting the imprint operation based on the feature. The correction information is, for example, information for correcting the imprint operation so as to reduce the bias of the progress (flow of the resist 22) of the contact region S between the template 10 and the resist 22.

The drive control unit 206 controls the drive of a mechanism (for example, the wafer stage 82, the pressurizing unit 84, the stage base 88, and the like) related to the imprint operation based on the correction information.

The output unit 207 outputs the correction information in a predetermined mode (for example, so as to notify the user).

As described above, according to the present embodiment, the feature based on the interference fringes R is acquired from the difference image illustrating the difference between the reference image and the imprint image. This makes it possible to reduce the influence of noise components (for example, the image of the edge of the wafer 20) contained in the imprint image, leading to high-accuracy detection of the interference fringes R, enabling high-accuracy evaluation of the imprint operation based on the interference fringes R.

(Example of Analysis Method Using Difference Image)

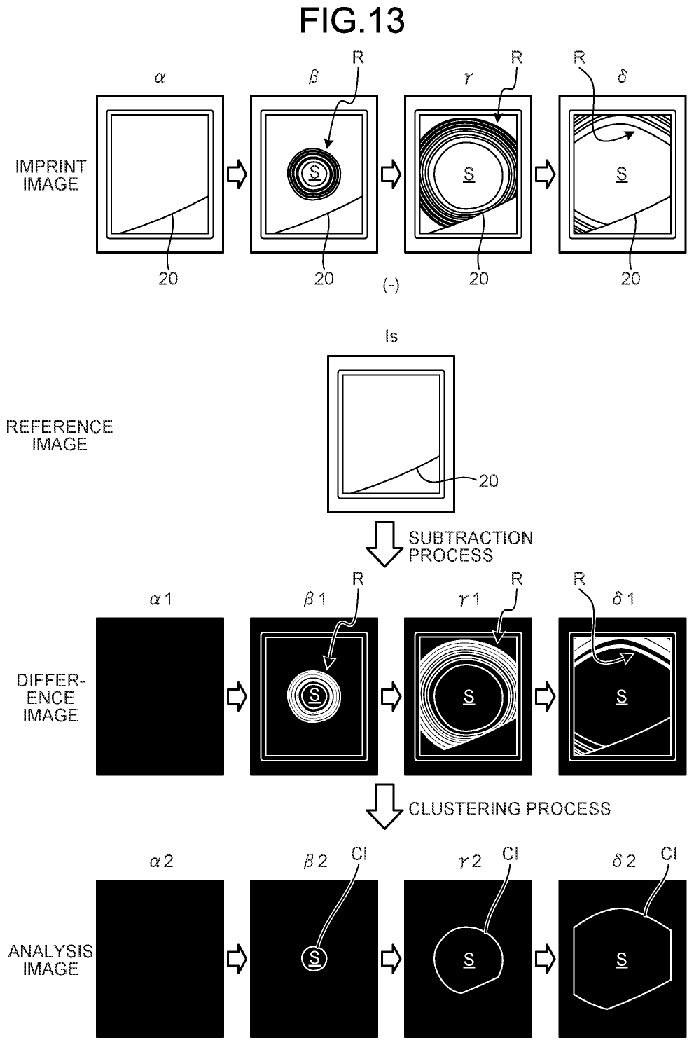

FIG. 13 is a diagram illustrating an example of an analysis method of the interference fringes R using difference images α1 to δ1 according to the embodiment. FIG. 13 illustrates a relationship between the imprint images α to δ, the reference image Is, the difference images α1 to δ1, and analysis images α2 to δ2.

The imprint images α to δ are captured images of the template 10 during the imprint operation, which are acquired by the imaging unit 80 at a certain imprint position. The imprint images α to δ illustrated here are a plurality of captured images acquired with the progress of the imprint operation at the time of a partial shot region, which are the same as the imprint images α to 6 described with reference to FIG. 10. As described above, the imprint images α to δ include an image of the edge of the wafer 20.

The reference image Is is a captured image of the template 10 before (immediately before) the imprint operation, which is acquired by the imaging unit 80 at the imprint position same as the imprint images α to δ. The reference image Is includes an image of the edge of the wafer 20 similarly to the imprint images α to δ.

The difference images α1 to δ1 are images representing a difference between the imprint images α to δ and the reference image Is, which is generated by the subtraction process of subtracting the reference image Is from the imprint images α to δ. The difference image α1 is an image representing the difference between the imprint image α and the reference image Is. The difference image β1 is an image representing the difference between the imprint image β and the reference image Is. The difference image γ1 is an image representing the difference between the imprint image γ and the reference image Is. The difference image δ1 is an image representing the difference between the imprint image δ and the reference image Is. In all the difference images α1 to δ1, the image of a part common to the imprint images α to δ and the reference image Is (such as the image of the edge of the wafer 20) has been removed, and the image of the interference fringe R is clarified.

The analysis images α2 to δ2 are images obtained by performing a clustering process on each of the difference images α1 to δ1. The analysis images β2 to β2 illustrate a clustering region Cl obtained by clustering the inside of the innermost fringe of the interference fringes R of the difference image β1. The clustering region Cl corresponds to the contact region S in which the resist 22 and the template 10 are in contact, in other words, the flow edge of the resist 22. From these analysis images α2 to δ2, it can be seen that the area of the clustering region Cl gradually expands with the progress of the imprint operation. Information related to such a clustering region Cl (contact region S or the flow edge of the resist 22) is treated as one of the features.

As described above, by using a plurality of difference images α1 to δ1 corresponding to a plurality of imprint images α to δ obtained with the progress of the imprint operation, it is possible to acquire features indicating changes over time in the clustering region Cl. By using the features including such a change over time, it is possible to more accurately evaluate and correct the imprint operation.

(Example of Features)

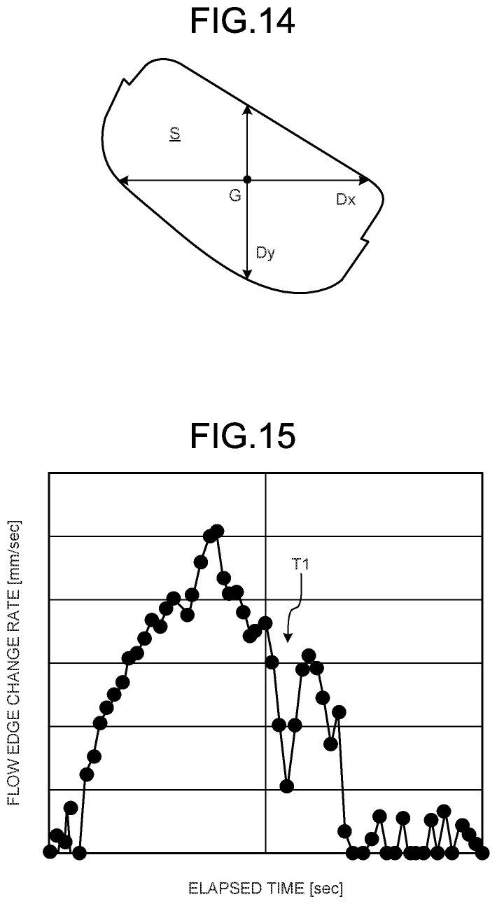

Examples of features will be described below with reference to FIGS. 14 to 24.

FIG. 14 is a diagram illustrating parameters related to features according to a first example. FIG. 15 is a graph illustrating an example of changes over time in the features according to the first example. The feature according to the first example is the flow edge change rate indicating the change rate of the distance from the center of gravity G of the contact region S (clustering region Cl) to the edge of the contact region S (flow edge of the resist 22).

In FIG. 14, a distance Dx indicates a distance from the center of gravity G on the X-axis in the X-Y coordinates to the flow edge, while a distance Dy indicates a distance from the center of gravity G on the Y-axis in the X-Y coordinates to the flow edge. The flow edge change rate indicates the change amount of the average value, the maximum value, or the minimum value of the distances Dx and Dy per unit time.

The horizontal axis of the graph in FIG. 15 indicates the elapsed time after the start of the imprint operation, and the vertical axis indicates the flow edge change rate. In the example illustrated in FIG. 15, the flow edge change rate gradually increases after the start of the imprint operation, reaches a peak at a certain point, and then gradually decreases, specifically momentarily greatly decreases at a certain timing Ti during the decrease. Detection of such a phenomenon leads to estimation that a certain problem has occurred at the timing T1. For example, there is a possibility of occurrence of a problem (variation, etc), at the timing T1, in conditions such as the pressure applied by the template 10 to the resist 22 (hereinafter referred to as pressing force), the moving speed of the template 10 (hereinafter referred to as the template speed), the positional relationship between the template 10 and the wafer 20 (hereinafter referred to as alignment state), back pressure Pb, or the like. Such a flow edge change rate can be effectively used even at the time of a partial shot region.

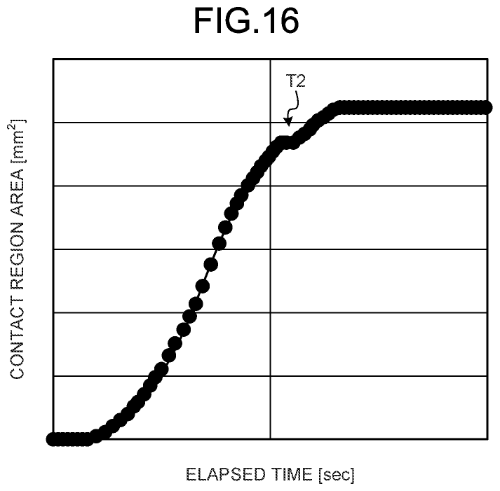

FIG. 16 is a graph illustrating an example of changes over time in the features according to the second example. The feature according to the second example is the contact region area indicating the area of the contact region S.

The horizontal axis of the graph of FIG. 16 indicates the elapsed time after the start of the imprint operation, and the vertical axis indicates the contact region area. In the example illustrated in FIG. 16, the contact region area gradually increases after the start of the imprint operation and converges to a certain value after a certain period of time, but the increase of the value stagnates at a certain timing T2 before the convergence. Detection of such a phenomenon leads to estimation that a certain problem has occurred at the timing T2. For example, there is a possibility of occurrence of a problem, at the timing T2, in conditions such as the pressing force, template speed, alignment state, tilt, back pressure Pb, or the like. Such a contact region area can be effectively used even at the time of a partial shot region.

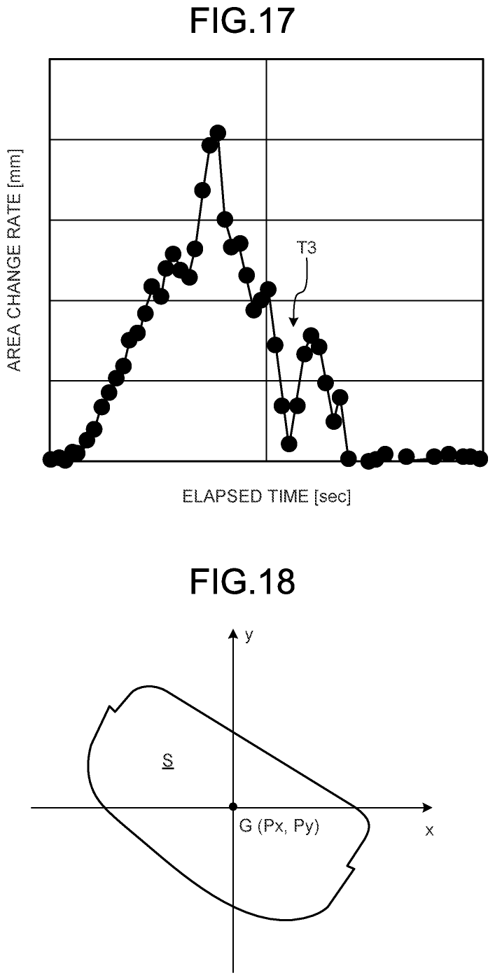

FIG. 17 is a graph illustrating an example of changes over time in the features according to a third example. The feature according to the third example is the area change rate indicating the change amount in the area of the contact region S per unit time.

The horizontal axis of the graph in FIG. 17 indicates the elapsed time after the start of the imprint operation, and the vertical axis indicates the area change rate. In the example illustrated in FIG. 17, the area change rate gradually increases after the start of the imprint operation, reaches a peak at a certain point, and then gradually decreases, specifically momentarily greatly decreases at a certain timing T3 during the decrease. Detection of such a phenomenon leads to estimation that a certain problem has occurred at the timing T3. For example, there is a possibility of occurrence of a problem, at the timing T3, in conditions such as the pressing force, template speed, alignment state, tilt, back pressure Pb, or the like. Such an area change rate can be effectively used even at the time of a partial shot region.

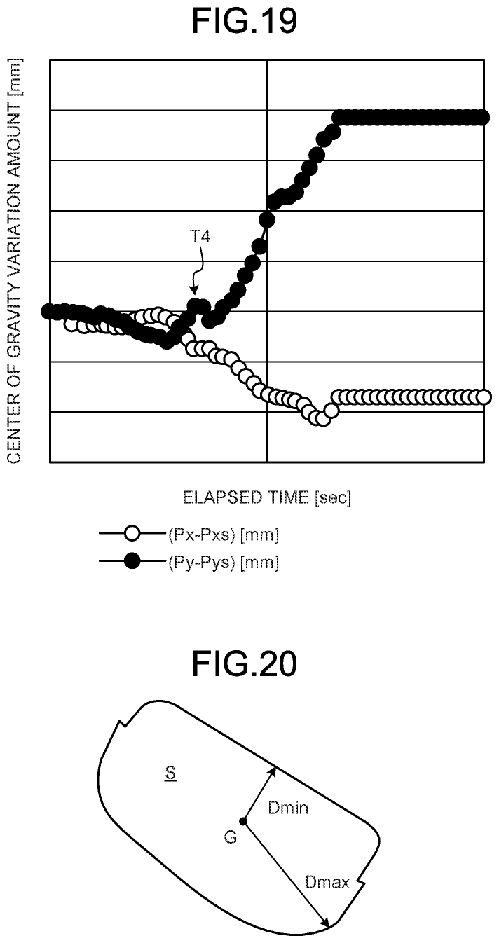

FIG. 18 is a diagram illustrating parameters related to features according to a fourth example. FIG. 19 is a graph illustrating an example of changes over time in the features according to the fourth example. The feature according to the fourth example is a center of gravity variation amount indicating the variation amount in the position of the center of gravity G in the contact region S.

In FIG. 18, a position Px indicates the position of the center of gravity G on the X-axis of the X-Y coordinates, and a position Py indicates the position of the center of gravity G on the Y-axis of the X-Y coordinates. The center of gravity variation amount indicates the amount of deviation of the position (Px, Py) of the center of gravity G of the contact region S (clustering region Cl of the analysis images α2 to δ2) during the imprint operation from a predetermined reference position (Pxs, Pys). The reference position may be, for example, the position of the center of gravity at the start of the imprint operation, the final position of the center of gravity in the previous imprint operation, a predetermined ideal center of gravity position, or the like.

The horizontal axis of the graph in FIG. 19 indicates the elapsed time after the start of the imprint operation, and the vertical axis indicates the center of gravity variation amount. In the graph, the line represented by white circles indicates the change over time of the variation amount (Px-Pxs) on the X-axis of the center of gravity G, while the line represented by black circles indicates the change over time of the variation amount (Py-Pys) on the Y-axis of the center of gravity G. In the example illustrated in FIG. 19, the center of gravity variation amount increases after a timing T4. Detection of such a phenomenon leads to estimation that a certain problem has occurred at the timing T4. For example, there is a possibility of occurrence of a problem, at the timing T4, in conditions such as the pressing force, template speed, alignment state, tilt, back pressure Pb, or the like.

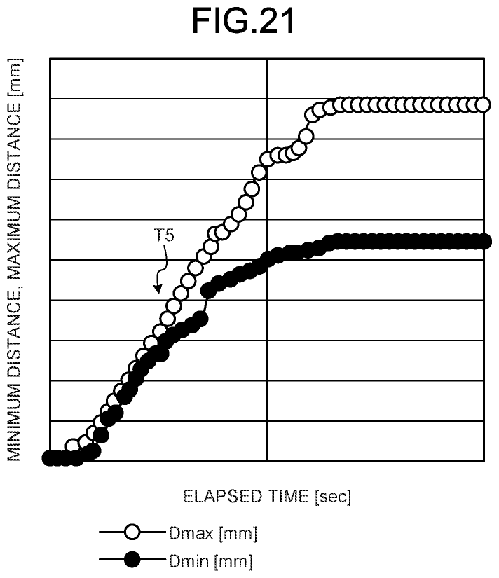

FIG. 20 is a diagram illustrating parameters related to features according to a fifth example. FIG. 21 is a graph illustrating an example of changes over time in the features according to the fifth example. The feature according to the fifth example is an edge distance difference indicating the minimum value and the maximum value in the distance from the center of gravity G of the contact region S to the edge of the contact region S (flow edge of the resist 22).

In FIG. 20, a minimum distance Dmin indicates a distance from the center of gravity G to the nearest edge, and a maximum distance Dmax indicates a distance from the center of gravity G to the farthest edge. The edge distance difference is information that enables comparison between the minimum distance Dmin and the maximum distance Dmax.

The horizontal axis of the graph in FIG. 21 indicates the elapsed time after the start of the imprint operation, and the vertical axis indicates the minimum distance Dmin and the maximum distance Dmax. In the graph, the line represented by white circles indicates the change over time of the maximum distance Dmax, while the line represented by black circles indicates the change over time of the minimum distance Dmin. In the example illustrated in FIG. 21, the difference between the minimum distance Dmin and the maximum distance Dmax gradually expands after a timing T5. Detection of such a phenomenon leads to estimation that a certain problem has occurred at the timing T5. For example, there is a possibility of occurrence of a problem, at the timing T5, in conditions such as the pressing force, template speed, alignment state, tilt, back pressure Pb, or the like.

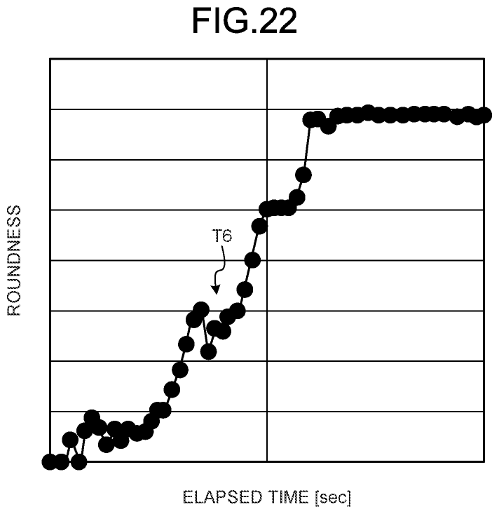

FIG. 22 is a graph illustrating an example of changes over time in the features according to a sixth example. The feature according to the sixth example is the roundness of the contact region S.

The horizontal axis of the graph of FIG. 22 indicates the elapsed time after the start of the imprint operation, and the vertical axis indicates the roundness of the contact region S. Although the method for calculating the roundness is not particularly limited, it is possible, for example, to calculate the roundness by using the difference between the maximum distance Dmax and the minimum distance Dmin as illustrated in FIG. 21. Here, {(Dmax−Dmin)/2} is defined as the roundness, in which the smaller the value of the roundness, the closer the shape to a perfect circle. In the example illustrated in FIG. 22, the roundness increases sharply after a timing T6. Detection of such a phenomenon leads to estimation that a certain problem has occurred at the timing T6. For example, there is a possibility of occurrence of a problem, at the timing T6, in conditions such as the pressing force, template speed, alignment state, tilt, back pressure Pb, or the like.

(Correcting Imprint Operation)

By using the above-described features, it is possible to generate correction information for improving the imprint operation. The correction information can be, for example, information for adjusting the pressing force, template speed, alignment state, tilt, back pressure Pb, or the like. By performing feedback control or the like based on the correction information for the mechanism related to the imprint operation of the imprint device 1, it is possible to improve the imprint operation. For example, it is possible to correct the imprint operation so as to reduce the deviation of the development of the contact region S. Although the feedback control is preferably performed in real time during the execution of the imprint operation, it may be performed aiming at improving the next imprint operation, or the like.

Furthermore, the features may be acquired for each of predetermined region divisions of the wafer 20, and the correction information for each of region divisions may be generated by using these features. The region division may be, for example, a central portion, an edge, an intermediate portion (an annular region between the central portion and the edge). It is allowable to use a plurality of pieces of correction information for individual region divisions to perform interpolation processing.

Furthermore, the correction information may be notified to the user (for example, the administrator of the imprint device 1) via a display or the like. With this notification, the user can appropriately adjust the mechanism related to the imprint operation based on the correction information, leading to improvement of the maintainability.

(Modification)

The above embodiment has described a case where the features are acquired by using the plurality of difference images α1 to δ1 corresponding to the plurality of imprint images α to δ accompanying the progress of the imprint operation. However, the embodiment of the present invention is not limited to this. For example, even with the use of a single difference image, an effective feature for improving the imprint operation can be acquired.

Furthermore, although the above embodiment illustrates a configuration in which the imprint device 1 includes the control unit 90, the control unit 90 may be configured independently of the imprint device. Furthermore, one control unit 90 may be configured to control a plurality of imprint devices.

The program that causes the computer (control unit 90) to execute the processes to implement the above-described functions can be created as a file in an installable format or an executable format, so as to be recorded in a computer-readable recording medium such as a compact disc (CD)-ROM, a flexible disk (FD), a CD-recordable (CD-R), or a digital versatile disk (DVD). In addition, the program may be provided or distributed via a network such as the Internet.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An imprint device comprising:
a holder that holds a template;
a stage on which a substrate is mounted;
an imaging device that acquires a captured image of the template; and
a controller that performs processes for controlling an imprint operation of pressing the template against a resin film disposed on the substrate based on the captured image,
wherein the controller
acquires, from the imaging device, a reference image which is the captured image of the template before the imprint operation at a predetermined imprint position, and an imprint image which is the captured image of the template during the imprint operation at the imprint position,
acquires features based on interference fringes appearing on the template during the imprint operation, from a difference image representing a difference between the reference image and the imprint image, and
performs a process for controlling the imprint operation based on the features.

2. The imprint device according to claim 1,
wherein the controller generates a plurality of the difference images corresponding to a plurality of the imprint images acquired with progress of the imprint operation, and generates the features including information indicating a change over time of a contact region between the template and the resin film, from the plurality of difference images.

3. The imprint device according to claim 2,
wherein the controller performs a process for correcting the imprint operation so as to reduce a deviation in development of the contact region.

4. The imprint device according to claim 3,
wherein the feature includes a flow edge change rate indicating a change rate of a distance from a center of gravity of the contact region to an edge of the contact region.

5. The imprint device according to claim 3,
wherein the feature includes an area change rate indicating a change amount in an area of the contact region per unit time.

6. The imprint device according to claim 3,
wherein the feature includes a center of gravity variation amount indicating a variation amount of a position of a center of gravity of the contact region.

7. The imprint device according to claim 3,
wherein the feature includes an edge distance difference indicating a minimum value and a maximum value in a distance from a center of gravity of the contact region to an edge of the contact region.

8. The imprint device according to claim 3,
wherein the feature includes a roundness of the contact region.

9. The imprint device according to claim 2,
wherein the contact region is a region obtained by clustering an inside of an innermost fringe of the interference fringes.

10. An information processing device configured to control an imprint device that forms a predetermined pattern on a resin film disposed on a substrate by performing an imprint operation of pressing a template against the resin film, the information processing device comprising:
a connecter connected to an imaging device that acquires a captured image of the template; and
a controller that performs processes for controlling the imprint operation based on the captured image,
wherein the controller
acquires, via the connecter, a reference image which is the captured image of the template before the imprint operation at a predetermined imprint position, and an imprint image which is the captured image of the template during the imprint operation at the imprint position,
acquires features based on interference fringes appearing on the template during the imprint operation, from a difference image representing a difference between the reference image and the imprint image, and
performs a process for controlling the imprint operation based on the features.

11. The information processing device according to claim 10,
wherein the controller generates a plurality of the difference images corresponding to a plurality of the imprint images acquired with progress of the imprint operation, and generates the features including information indicating a change over time of a contact region between the template and the resin film, from the plurality of difference images.

12. The information processing device according to claim 11,
wherein the controller performs a process for correcting the imprint operation so as to reduce a deviation in development of the contact region.

13. The information processing device according to claim 12,
wherein the feature includes a flow edge change rate indicating a change rate of a distance from a center of gravity of the contact region to an edge of the contact region.

14. The information processing device according to claim 12,
wherein the feature includes an area change rate indicating a change amount in an area of the contact region per unit time.

15. The information processing device according to claim 12,
wherein the feature includes a center of gravity variation amount indicating a variation amount of a position of a center of gravity of the contact region.

16. The information processing device according to claim 12,
wherein the feature includes an edge distance difference indicating a minimum value and a maximum value in a distance from a center of gravity of the contact region to an edge of the contact region.

17. The information processing device according to claim 12,
wherein the feature includes a roundness of the contact region.

18. The information processing device according to claim 13,
wherein the contact region is a region obtained by clustering an inside of an innermost fringe of the interference fringes.

19. An imprint method of forming a predetermined pattern on a resin film disposed on a substrate by performing an imprint operation of pressing a template against the resin film, the imprint method comprising:
acquiring a captured image of the template by an imaging device;
acquiring, from the imaging device by an information processing device, a reference image which is the captured image of the template before the imprint operation at a predetermined imprint position and an imprint image which is the captured image of the template during the imprint operation at the imprint position;
acquiring, by the information processing device, features based on interference fringes appearing on the template during the imprint operation, from a difference image representing a difference between the reference image and the imprint image; and
performing, by the information processing device, a process for controlling the imprint operation based on the features.

20. The imprint method according to claim 19, further comprising:
generating, by the information processing device, a plurality of the difference images corresponding to a plurality of the imprint images acquired with progress of the imprint operation; and
generating, by the information processing device, the features including information indicating a change over time of a contact region between the template and the resin film, from the plurality of difference images.
